(19) United States
(12) Patent Application Publication
(10) Pub. No.: US 2007/0141788 A1
(43) Pub. Date: Jun. 21, 2007

(54) Method for embedding non-volatile memory with logic circuitry

(76) Inventors: Ilan Bloom, Haifa (IL); Eli Lusky, Tel-Aviv (IL)

Correspondence Address: EMPK & SHILOH, LLP, 116 JOHN ST,, SUITE 1201, NEW YORK, NY, 10038, US

(21) Appl. No.: 11/604,237

(22) Filed: Nov. 27, 2006

Related U.S. Application Data
(63) Continuation-in-part of application No. 11/137,042, filed on May 25, 2005.

(51) Int. Cl. H01L 21/8234

(52) U.S. Cl. 438/275

(57) ABSTRACT

A method for embedding NROM process steps and HV CMOS devices into high-speed logic CMOS process steps, the method including forming isolation areas for NROM and high voltage CMOS elements, forming high thermal drive process elements of the NROM and the HV CMOS elements, forming mid thermal drive process elements of the logic CMOS elements, and forming low thermal drive process elements for the logic CMOS and for the NROM and the high voltage CMOS elements.

### CROSS-REFERENCE TO RELATED APPLICATIONS

The present application is a continuation-in-part application of, and claims priority from, U.S. patent application Ser. No. 11/137,042, filed 25 May 2005, which is incorporated herein by reference.

### FIELD OF THE INVENTION

The present invention relates generally to methods for embedding non-volatile memories with logic circuitry, such as but not limited to, high speed, low voltage CMOS.

### BACKGROUND OF THE INVENTION

It is possible to combine memories with logic, this being referred to in the literature as “embedded memories”. A type of memory of particular importance in embedded applications is the non-volatile memory (NVM), such as but not limited to, EPROM (Electrically Programmable Read Only Memory) and EEPROM (Electrically Erasable Programmable Read Only Memory), Flash and single or multi-level NVM cells or combinations. The memory element is formed by a transistor with a floating gate whose threshold voltage is determined by the written information in the form of electric charge on the floating gate electrode. The control gate on the one hand serves to detect what the threshold voltage (the written information) is during reading and on the other hand to influence the potential of the floating gate during writing and/or erasing. Such memories may be embedded with CMOS (complementary metal oxide semiconductor) logic circuitry.

Manufacturing embedded memories poses many challenges because the normal processing techniques for non-volatile memories are not readily integrated with the normal processing techniques for logic circuitry. Embedding NVM capabilities into high speed MOS entails incorporating manufacturing steps for the NVM devices as well as steps for high voltage CMOS elements typically needed for the operation of the NVM memory elements.

However, the manufacturing steps for forming the NVM and high voltage components are not readily combined together with the steps for forming the logic elements. This forces the manufacturer to dramatically alter the processes normally used to form the logic elements. The manufacturer thus cannot use the normal workflow and assembly line to make embedded memories into the standard low-voltage logic CMOS.

The extra manufacturing steps needed to incorporate NVM and HV CMOS may affect the high speed CMOS performance. Typically incorporation efforts lead to a compromise in performance of both NVM and fast CMOS devices, forcing the manufacturer to modify the design libraries available for the fast logic CMOS that were no longer valid due to the degradation of the fast CMOS transistor parameters.

It is noted that where applicable, descriptions involving NROM (Nitride Read Only Memory) are intended specifically to include related oxide-nitride technologies, including SONOS (Silicon-Oxide-Nitiide-Oxide-Silicon), MNOS (Metal-Nitride-Oxide-Silicon), MONOS (Metal-Oxide-Nitride-Oxide-Silicon) and the like used for NVM devices. Further description of NROM and related technologies may be found at:

“Non Volatile Memory Technology”, 2005 published by Saifun Semiconductor and materials presented at and through http://siliconnexus.com,
“Design Considerations in Scaled SONOS Nonvolatile Memory Devices” found at:

http://klabs.org/richcontent/MemoryContent/nvmt_-symp/nvmts_{—}2000/presentations/bu_white_sonos_lehigh univ.pdf,

“SONOS Nonvolatile Semiconductor Memories for Space and Military Applications” found at:

http://klabs.org/richcontent/MemoryContent/nvmt_symp/nvmts_{—}2000/papers/adams_d.pdf,

“Philips Research—Technologies—Embedded Nonvolatile Memories” found at:

http://research.philips.com/technologies/ics/nvmemories/index.html, and

“Semiconductor Memory: Non-Volatile Memory (NVM)” found at: http://ece.nus.edu.sg/stfpage/elezhucx/myweb/NVM.pdf, all of which are incorporated by reference herein in their entirety.

### SUMMARY OF THE INVENTION

The present invention seeks to provide methods for embedding non-volatile memories and HV CMOS circuitry into an existing logic low-voltage CMOS process, as is described more in detail herein below, without changing performance of both the logic circuitry and the NVM elements and without changing a sequence of manufacturing steps for both the logic circuitry and the NVM elements. The embedding process includes insertion of the NVM process steps into an existing logic CMOS process in a way that maintains the CMOS performance, enabling to use existing circuit libraries. The CMOS devices parameters are not degraded due to such a combination of elements, and there is no penalty in performance or reliability.

The invention is applicable, for example, for forming one bit, dual-bit or multi-bit NVM cells, such as but not limited to, Nitride Read Only Memory (NROM) cells, embedded with logic circuitry in one chip.

In accordance with an embodiment of the present invention, a process is provided that incorporates (embeds) the NVM NROM device and HV CMOS devices into the high-speed logic CMOS. Some of the manufacturing steps may serve for more than one device type, whereas other steps may be dedicated to a specific device. In one embodiment, in the overall sequence of steps, there are no changes in the NVM, HV and logic low voltage CMOS sequences. The high thermal drive manufacturing steps of NVM and HV CMOS are integrated early in the general flow to avoid influence on the LV high speed CMOS devices

There is thus provided in accordance with an embodiment of the present invention a method for embedding NROM process steps and HV CMOS devices into high-speed logic CMOS process steps, the method including forming isolation areas for logic CMOS and for NROM and high voltage CMOS elements, forming high thermal drive process elements of the NROM and the high voltage (HV) CMOS elements, forming mid thermal drive process elements of the logic CMOS elements, and forming low thermal drive process elements for the logic CMOS and for the NROM and the high voltage CMOS elements

In accordance with an embodiment of the present invention the method may further include forming a pocket implant near a bit line associated with the NROM elements.

In accordance with an embodiment of the present invention the method may further include providing a spacer adapted to decouple between the pocket implant and the bit line. The pocket implant may include a double pocket implant, wherein the double pocket implant includes a p+ implant near a surface of a substrate for the NROM elements and an n− implant below the p+ implant.

In accordance with an embodiment of the present invention the method may further include adjusting a work function of a gate terminal of at least one of the NROM elements. This may include implementing n-type doping in a polysilicon gate layer of the at least one of the NROM elements. Alternatively this may include implementing p-type doping in a polysilicon gate layer of the at least one of the NROM elements.

In accordance with an embodiment of the present invention isolation areas for the logic CMOS and for the NROM and high voltage CMOS elements may be identical.

In accordance with an embodiment of the present invention isolation areas for the NROM elements may be shallower STI, or instead, deeper STI.

There is also provided in accordance with an embodiment of the present invention a method of fabricating a composite logic and non-volatile memory integrated circuit including forming isolation areas for non-volatile memory (NVM) elements and high voltage (HV) logic devices, forming high thermal drive process elements of the NVM elements and the HV logic devices, forming mid thermal drive process elements of logic elements, and forming low thermal drive process elements for the logic elements and for the NVM elements and the HV logic devices.

There is also provided in accordance with an embodiment of the present invention a composite logic and non-volatile memory integrated circuitry including isolation areas for non-volatile memory (NVM) elements and high voltage (HV) logic devices, high thermal drive process elements of the NVM elements and the HV logic devices, mid thermal drive process elements of logic elements, and low thermal drive process elements for the logic elements and for the NVM elements and the HV logic devices.

### BRIEF DESCRIPTION OF THE DRAWINGS

The present invention will be understood and appreciated more fully from the following detailed description taken in conjunction with the appended drawings in which:

FIG. 1 is a generalized method for combining non-volatile memory devices and HV CMOS devices with existing high speed LVCMOS process, in accordance with an embodiment of the present invention;

FIG. 2 is a more specific, non-limiting example of a process chart for embedding non-volatile memories with logic circuitry, in accordance with an embodiment of the present invention; and

FIG. 3 describes a non-limiting example of a mask sequence for embedded process flow, integrating the existing LV and mid voltage (MV) devices with HV CMOS devices and NROM devices, in accordance with an embodiment of the present invention.

### DETAILED DESCRIPTION OF THE PRESENT INVENTION

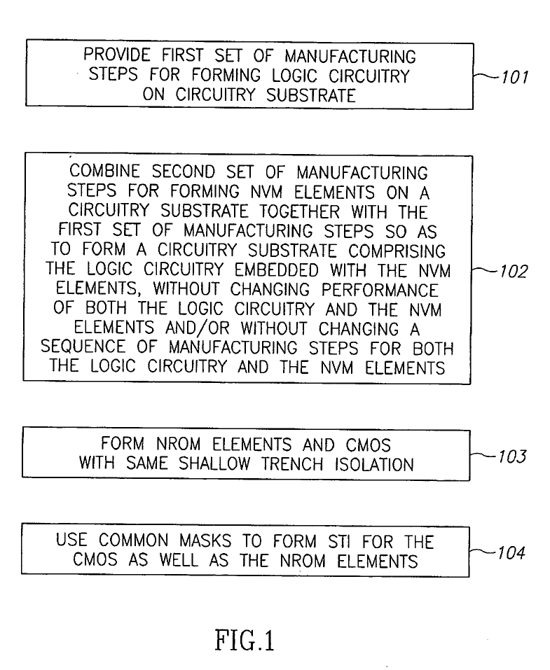

Reference is now made to FIG. 1, which illustrates a method for embedding non-volatile memories with logic circuitry, in accordance with an embodiment of the present invention.

A first set of manufacturing steps may be given and defined for forming logic circuitry on a circuitry substrate (step 101). The first set of manufacturing steps may be a standard set of processes with masks for forming different circuit features, such as but not limited to, p-wells, n-wells, junctions, contacts, vias, metal lines, poly lines and the like. The first set of manufacturing steps may be standard manufacturing steps for manufacturing high speed, low voltage CMOS logic, for example. The first set of manufacturing steps is independent from the manufacturing steps used to make non-volatile memory elements. In other words, the first set of manufacturing steps may be used to manufacture logic circuitry without any connection to embedding non-volatile memory elements. This is in contrast with the prior art which must use some special set of logic manufacturing steps, which is a modification of the normal manufacturing steps used to make logic, in order to embed memory with the logic circuitry.

In accordance with an embodiment of the present invention, a second set of manufacturing steps is provided for forming NVM elements and HV CMOS on a circuitry substrate. This second set of manufacturing steps is combined together with the first set of manufacturing steps so as to form a circuitry substrate comprising the logic circuitry embedded with the NVM elements and HV CMOS, without changing performance of both the logic circuitry and the NVM elements, and/or without changing each sequence of manufacturing steps for forming the logic circuitry and NVM elements (step 102).

It is noted that “high voltage”, such as in high voltage CMOS elements, is a relative term and depends upon the application. For example, high voltage may mean at least 3 V, or more than 6 V.

The process of embedding includes merging the individual process flows of existing high speed logic CMOS, HV CMOS devices and NVM elements, so that in the combined embedded flow, each subset sequence for each of the three elements (high speed logic CMOS, HV CMOS devices and NVM elements) is not changed. The merging may include placing some high thermal drive process steps early in the combined flow, such as (but not restricted to) ONO formation and/or HV GOX (gate oxide) formation. Mid thermal drive process steps may be placed later in the flow. Finally, sensitive steps that are not to be exposed to high thermal drive are placed as late as possible in the combined flow.

“Without changing performance of both the logic circuitry and the NVM elements” means that both the logic circuitry and the NVM elements perform as if they were manufactured with the same manufacturing steps on separate circuitry substrates. “Without changing the sequence of manufacturing steps” means that none of the manufacturing steps is altered individually or collectively, and the order of the steps remains the same.

In accordance with an embodiment of the present invention, the NVM elements formed with the second set of manufacturing steps may be nitride, read only memory (NROM) elements. The NROM elements and the CMOS may be formed with the same trenches of the shallow trench isolation (STI) (step 103). This may be advantageous due to the fact that a common mask may be used to form STI for the logic as well as the NROM elements (step 104). Trenches provided for the STI may be etched by means of a mask, and the trenches may be subsequently filled with oxides, for example. Other masks or process steps may also be combined if possible, in order to save steps.

Using STI to form NROM elements is a known technique. For example, U.S. Pat. No. 6,794,249 to Willer et al. describes a non-volatile memory cell with an ONO (oxide-nitride-oxide) layer, which may be used in a virtual-ground architecture, wherein the active region of the cell is isolated by STI. U.S. Pat. NO. 6,794,249, the disclosure of which is incorporated herein by reference, may be used to make NROM cells, for example, or any kind of cell constructed with SONOS (semiconductor-oxide-nitride-oxide-semiconductor). Such cells (e.g., NROM and SONOS) may be programmed by channel-hot electrons and may be erased using hot holes.

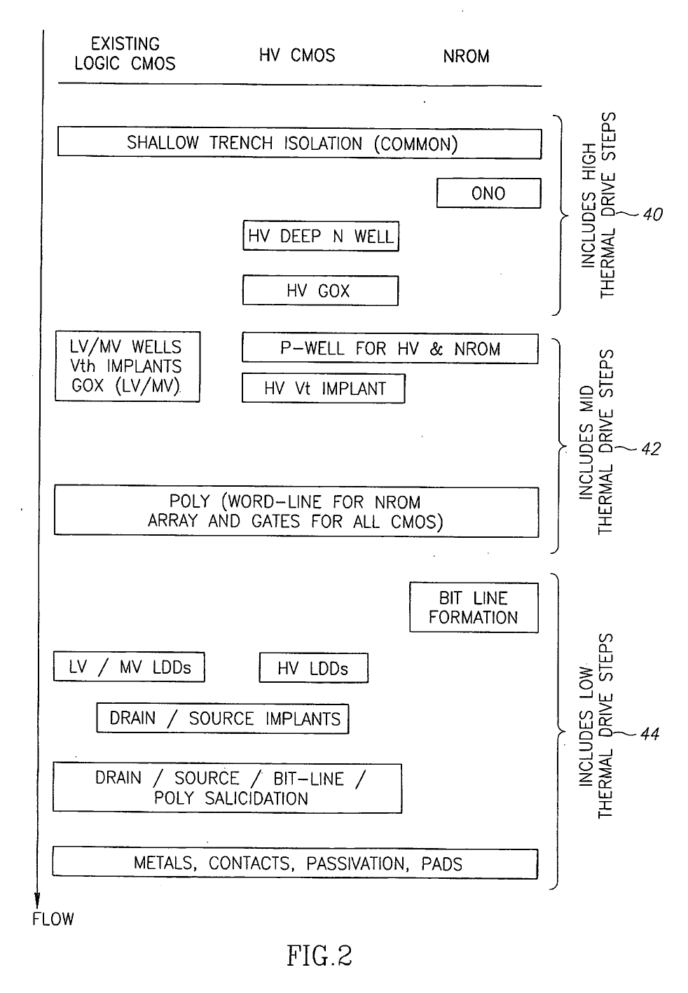

Reference is now made to FIG. 2, which is a more specific, non-limiting example of a process chart for embedding non-volatile memories with logic circuitry, in accordance with an embodiment of the present invention. It is emphasized that the process steps are merely for exemplary purposes only, and the invention is not limited in any way to this example.

As mentioned above, high thermal drive process steps (indicated by reference numeral 40) may be placed early in the combined flow, such as but not limited to, ONO formation and/or HV GOX formation. Some processes which are not high thermal drive steps may be performed about the same time as the high thermal drive steps. For example, the common STI may be formed before the ONO and a high voltage deep n well may be formed before the HV GOX. Mid thermal drive process steps (indicated by reference numeral 42) may follow, including but not limited to low voltage/mid voltage GOX for the existing logic CMOS, high voltage threshold voltage dopant for the HV CMOS,. Finally, sensitive steps (referred to as low thermal drive steps, indicated by reference numeral 44) that should not be exposed to high thermal drive are placed as late as possible in the combined flow. Such steps may include without limitation, bit line formation for the NROM, low voltage/mid voltage LDDs (lightly doped drains) for the existing logic CMOS, HV LDDs for the HV CMOS, drain and source implants and drain/source/bit-line/poly gate salicidation for the existing logic CMOS and the HV CMOS. Metallization, contacts, passivation and pads may be formed for all three elements.

It is noted that the order of forming some of the high thermal drive and mid thermal drive steps may be modified in accordance with different embodiments of the invention. For example, the HV p-well or cell-well or both may be implemented (formed) before/during/after ONO formation, or before/during/after MV GOX formation, or before/during/after LV GOX formation. Some implants may be implemented (formed) before one of the GOX steps. A bit-line implant may be implemented (formed) after poly implants.

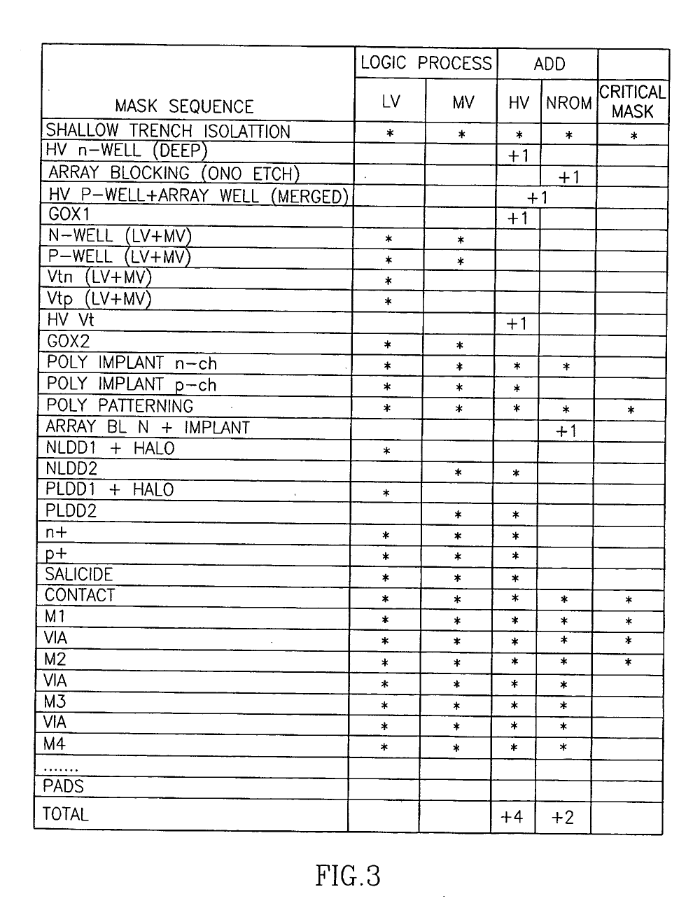

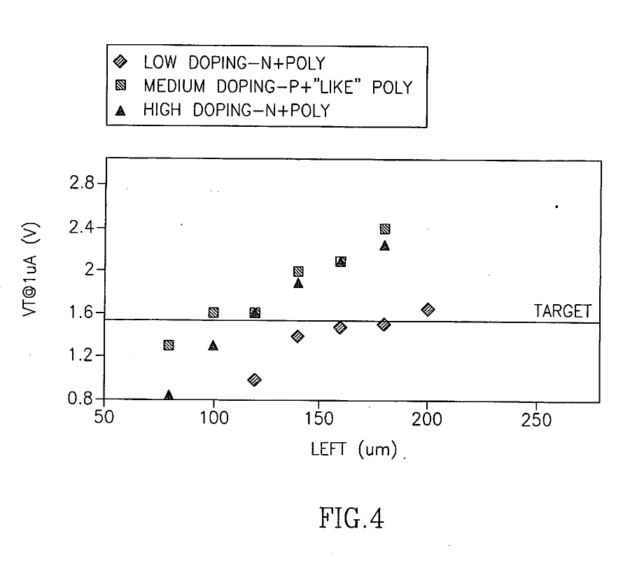

Reference is now made to FIG. 3, which is a more specific, non-limiting example of a mask sequence for embedded process flow, integrating the existing LV and mid voltage devices with HV CMOS devices and NROM devices, in accordance with an embodiment of the present invention. It is emphasized that these steps are merely for exemplary purposes only, and the invention is not limited in any way to this example.

In the illustrated non-limiting example, not only the shallow isolation trenches for the LV and MV logic, high voltage elements and the NROM may by etched with a single common mask. In other words, in the first step, isolation is formed for all devices—logic CMOS, high voltage elements and the NROM.

Afterwards, a high voltage deep n-well may be formed. A high voltage deep p-well may be formed along with an array well, merged into one well. An array blocking ONO region may then be formed to etch out the ONO in the CMOS circuitry region. Afterwards, a first, high voltage gate oxide layer may be formed, followed by a low voltage/mid voltage n-well and a low voltage/mid voltage p-well. A threshold voltage n-dopant (Vtn) and a threshold voltage p-dopant (Vtp) may then be introduced ( e.g., combined low and medium voltage) and also a HV Vt implant. MV and LV gates oxide may be formed later followed by poly deposition. The poly may be typically heavily n+ or p+ doped depending on the device type; n+ doped for NMOS and p+ for PMOS. Poly patterning and array bit line and other implants may then be implemented. One or more lightly doped source/drain extension implants NLDD (n lightly doped drain) and PLDD (p lightly doped drain) may then be formed. Typically, HV requires dedicated implant while MV/LV requires additional implant(s). Afterwards, n+ and p+ dopants may be implemented for all devices (LV may require a modified implant), polysalicide, contacts, metallized layers, vias and pads may be formed later. The dopants may involve a masked implantation of boron, phosphorus and other species and subsequent annealing of the dopings, for example, as is known in the art.

In accordance with an embodiment of the present invention, the dopant may include a pocket implant added as an integral NROM module. The pocket implant may be formed near at least one of the bit lines. Optionally, a spacer may be used to decouple between the pocket implant and the bit line. In accordance with another embodiment of the present invention, the NROM cell can include a double pocket implant near at least one of the bit lines wherein the double pocket implant is formed of two pocket implants, a p+ implant near a surface of the substrate and an n− implant below the p+ implant. Such a double pocket implant is described, for example, in U.S. Pat. No. 6,429,063 to Eitan, the disclosure of which is incorporated herein by reference.

In accordance with yet another embodiment of the present invention, the reliability of the memory device may be improved by adjusting the work function of the gate terminal of the NROM device. Such an option is discussed in the copending U.S. patent application Ser. No. 11/253,272, filed 17 Oct. 2005, the disclosure of which is incorporated herein by reference. In the past, NROM devices have used n-type doping (e.g., phosphorus) of the polysilicon gate, In contrast, p-type doping (e.g., boron) may be implemented in the polysilicon gate layer. Referring to FIG. 4, it may be seen that the threshold voltage Vt associated with the p+ doped polysilicon may be approximately 1V higher than the prior art n+ doping, for the same doping concentration.

Further, in accordance with another embodiment of the invention, the p+ doped polysilicon gate cell may have lower channel doping than that of the prior art n+ doped NROM while maintaining the same Vt, thereby providing the benefits of higher bit line breakdown voltage and reduced retention loss.

It is seen from the example illustrated in FIG. 3, that it is possible to form the NROM elements by adding no more than two additional masks, and to form the relatively high voltage circuitry elements by adding no more than four-six additional masks. It is contemplated that even with more complicated circuitry, it is possible to form the NROM elements by adding no more than 4-6 additional masks, and to form the high voltage circuitry elements with the NROM elements by adding a total of no more than 7-8 additional masks. It is further contemplated that with certain relatively simple circuitry, it is possible to form the NROM elements by adding just one additional mask and to form the relatively high voltage circuitry elements by adding just one additional mask.

It is noted that for the sake of simplicity and clarity, detailed steps involved with the masking and etching have not been specified (e.g., applying and removing protect layers, thermal oxidation, cleaning, etc.). Such processes are well known to those skilled in the art and do not require further description for the skilled artisan.

In summary, in accordance with a non-limiting embodiment of the invention, the invention may be used to incorporate more than one NVM architecture in the same process flow, such as but not limited to, EPROM (electrically programmable read only memory), EEPROM (electrically erasable programmable read only memory), OTP (one time programming), flash, code flash, data flash, serial flash, ROM (read only memory) replacement, and single or multiple NVM cells.

It will be appreciated by persons skilled in the art that the present invention is not limited by what has been particularly shown and described herein above. Rather the scope of the invention is defined by the claims that follow:

What is claimed is:

1. A method for embedding NROM (Nitride Read Only Memory) process steps and HV (high voltage) CMOS (complementary metal oxide semiconductor) devices into high-speed logic CMOS process steps, the method including:
forming isolation areas for NROM and high voltage CMOS elements;
forming high thermal drive process elements of said NROM and said HV CMOS elements;
forming mid thermal drive process elements of logic CMOS elements; and
forming low thermal drive process elements for said logic CMOS elements and for said NROM and said high voltage CMOS elements.

2. The method according to claim 1, further comprising forming a pocket implant near a bit line associated with said NROM elements.

3. The method according to claim 2, further comprising providing a spacer adapted to decouple between said pocket implant and said bit line.

4. The method according to claim 2, wherein said pocket implant comprises a double pocket implant.

5. The method according to claim 4, wherein said double pocket implant comprises a p+ implant near a surface of a substrate for said NROM elements and an n− implant below the p+ implant.

6. The method according to claim 1, further comprising adjusting a work function of a gate terminal of at least one of the NROM elements.

7. The method according to claim 6, wherein adjusting the work function comprises implementing n-type doping in a polysilicon gate layer of said at least one of the NROM elements.

8. The method according to claim 6, wherein adjusting the work function comprises implementing p-type doping in a polysilicon gate layer of said at least one of the NROM elements.

9. The method according to claim 1, wherein isolation areas for the logic CMOS elements and for the NROM and high voltage CMOS elements are identical.

10. The method according to claim 1, wherein isolation areas for the NROM elements are shallower STI (shallow trench isolation)

11. The method according to claim 1, wherein isolation areas for NROM elements are deeper STI.

12. The method according to claim 1, further comprising forming isolation areas for said logic CMOS elements together with said isolation areas for said NROM and said high voltage CMOS elements.

13. A method of fabricating a composite logic and non-volatile memory integrated circuit comprising:
forming isolation areas for non-volatile memory (NVM) elements and high voltage (HV) logic devices;
forming high thermal drive process elements of said NVM elements and said HV logic devices;
forming mid thermal drive process elements of logic elements; and
forming low thermal drive process elements for said logic elements and for said NVM elements and said HV logic devices.

14. The method according to claim 13, further comprising forming a pocket implant near a bit line associated with said NVM elements.

15. The method according to claim 14, further comprising providing a spacer adapted to decouple between said pocket implant and said bit line.

16. The method according to claim 14, wherein said pocket implant comprises a double pocket implant.

17. The method according to claim 16, wherein said double pocket implant comprises a p+ implant near a surface of a substrate for said NVM elements and an n− implant below the p+ implant

18. The method according to claim 13, further comprising adjusting a work function of a gate terminal of at least one of the NVM elements.

19. The method according to claim 18, wherein adjusting the work function comprises implementing n-type doping in a polysilicon gate layer of said at least one of the NVM elements.

20. The method according to claim 18, wherein adjusting the work function comprises implementing p-type doping in a polysilicon gate layer of said at least one of the NVM elements.

21. The method according to claim 13, wherein isolation areas for the logic elements and for the NVM and high voltage elements are identical.

22. The method according to claim 13, wherein isolation areas for the NROM elements are shallower STI.

23. The method according to claim 13, wherein isolation areas for NROM elements are deeper STI.

24. The method according to claim 13, further comprising forming isolation areas for said logic CMOS elements together with said isolation areas for said NROM and said HV logic devices.

25. A composite logic and non-volatile memory integrated circuitry comprising:
isolation areas for non-volatile memory (NVM) elements and high voltage (HV) logic devices;
high thermal drive process elements of said NVM elements and said HV logic devices;
mid thermal drive process elements of logic elements; and
low thermal drive process elements for said logic elements and for said NVM elements and said HV logic devices.

26. The circuitry according to claim 25, further comprising a pocket implant near a bit line associated with said NVM elements.

27. The circuitry according to claim 26, further comprising a spacer adapted to decouple between said pocket implant and said bit line.

28. The circuitry according to claim 26, wherein said pocket implant comprises a double pocket implant.

29. The circuitry according to claim 16, wherein said double pocket implant comprises a p+ implant near a surface of a substrate for said NVM elements and an n− implant below the p+ implant.

30. The circuitry according to claim 25, wherein isolation areas for the logic elements and for the NVM and high voltage elements are identical.

31. The circuitry according to claim 25, wherein isolation areas for the NROM elements are shallower STI.

32. The circuitry according to claim 25, wherein isolation areas for NROM elements are deeper STI.

33. The circuitry according to claim 25, further comprising isolation areas for said logic CMOS elements that are formed together with said isolation areas for said NROM and said HV logic devices.

34. A method for embedding NROM (Nitride Read Only Memory) and HV (high voltage) CMOS (complementary metal oxide semiconductor) devices into high-speed logic CMOS devices comprising:
designating isolation areas for NROM and high voltage CMOS elements; forming elements requiring a relatively higher thermal process drive prior to forming elements requiring a relatively lower thermal process drive.

35. A method of fabricating a composite logic and non-volatile memory integrated circuit comprising:
designating isolation areas for NROM and high voltage CMOS elements;
forming elements requiring a relatively higher thermal process drive prior to forming elements requiring a relatively lower thermal process drive.

36. A composite logic and non-volatile memory integrated circuitry comprising:
three or more sets of elements, wherein each set of elements is associated with a distinct thermal process drive level.
